(19) United States
(12) Patent Application Publication
(10) Pub. No.: US 2018/0356445 A1
(43) Pub. Date: Dec. 13, 2018

(54) TEST AND MEASUREMENT INSTRUMENT THAT USES MEASUREMENT PRECONDITIONS FOR MAKING MEASUREMENTS

(71) Applicant: Tektronix, Inc., Beaverton, OR (US)

(72) Inventors: David C. Vollum, Portland, OR (US); Seamus L. Brokaw, Hillsboro, OR (US); Byron T. Faber, Beaverton, OR (US); Keith D. Rule, Beaverton, OR (US)

(73) Assignee: Tektronix, Inc., Beaverton, OR (US)

(21) Appl. No.: 16/003,084

(22) Filed: Jun. 7, 2018

Related U.S. Application Data
(60) Provisional application No. 62/517,783, filed on Jun. 9, 2017.
(60) Provisional application No. 62/528,944, filed on Jul. 5, 2017.

(51) Int. Cl. G01R 13/02

(52) U.S. Cl. CPC G01R 13/0272

(57) ABSTRACT

A test and measurement instrument including an interface configured to receive one or more preconditions for data acquisition, the one or more preconditions defining one or more rules to which data received during the data acquisition is to conform, and one or more processors. The one or more processors are configured to receive the one or more preconditions for data acquisition, determine whether the test and measurement instrument can be configured to implement the one or more preconditions for data acquisition, configure the test and measurement instrument to implement the one or more preconditions for data acquisition when the test and measurement instrument can be configured to implement the one or more preconditions for data acquisition, and generate one or more alerts when the test and measurement instrument cannot be configured to implement the one or more preconditions for data acquisition.

### CROSS REFERENCE TO RELATED PATENT APPLICATIONS

This application claims benefit of U.S. Provisional Application No. 62/571,783, filed Jun. 9, 2017, titled USING MEASUREMENT PRECONDITIONS FOR MAKING VALID MEASUREMENTS, and U.S. Provisional Application No. 62/528,944, filed Jul. 5, 2017, titled DEFINING AUTO-RANGING GOALS BY EXAMPLE, each of which is incorporated by reference herein in its entirety.

### TECHNICAL FIELD

Embodiments of the disclosure are directed to test and measurement instruments, and more particularly, to configuring a test and measurement instrument based on measurement preconditions.

### BACKGROUND

Test and measurement instruments, such as oscilloscopes, may be controlled by a person through a user interface of the test and measurement instrument. Generally, the test and measurement instrument is controlled by knobs, buttons, and other controls typically found on the test and measurement instrument's front panel, as well as using a touchscreen that may be present on the display screen of many modern test and measurement instruments.

Test and measurement instruments may also be controlled through a programmatic interface (PI) of the test and measurement instrument. Generally, this may be done by sending predefined commands to the test and measurement instrument over a wired or wireless instrument communication link. Common communication links include the General Purpose Instrument Bus (GPIB), Universal Serial Bus (USB), Ethernet, WiFi, etc. Users often write test programs to send a series of PI commands to a test and measurement instrument to automate setting up the instrument to take a particular measurement. Such test programs may be part of an Automated Test System (ATS) which are often used in manufacturing or quality control operations for performing desired sequences of tests or measurement on a device under test (DUT).

Some test and measurement instruments, such as TBS1000 or TBS1000 EDU oscilloscopes by Tektronix, Inc., include a feature known as “Autorange,” which allows the test and measurement instrument to automatically scale the horizontal and vertical components to allow the test and measurement instrument to “track” a signal on a channel even if it changes or the user transfers to another signal on a different channel. This feature allows the user to focus entirely on their work without worrying about manipulating the front panel of the scope. However, the existing Autorange feature has a fixed definition for how the “tracked” signal should look on screen, and does not allow a user to change this definition.

Embodiments of the disclosure address these and other issues of the prior art.

### BRIEF DESCRIPTION OF THE DRAWINGS

FIG. 1 is a block diagram of a test and measurement instrument according to embodiments of the disclosure.

FIG. 2 is an example operation of a test and measurement instrument according to embodiments of the disclosure.

FIG. 3 is another example operation of a test and measurement instrument according to embodiments of the disclosure.

### DETAILED DESCRIPTION

The present disclosure discusses a test and measurement instrument having an interface, such as a programmatic interface, to receive one or more preconditions for data acquisition. The one or more preconditions define one or more rules to which data received during the data acquisition is to conform. The test and measurement instrument may also have at least one processor. The processor can receive the one or more preconditions for data acquisition, and determine whether the test and measurement instrument can be configured to implement the one or more preconditions for data acquisition. If the test and measurement instrument can be configured such that the data meets the one or more preconditions, then the test and measurement is configured in such a manner. If not, then an error is generated indicating that the data and/or the configurations do not meet the preconditions. In some embodiments, the preconditions may be dependent on the data. Further, in some embodiments, rather than receiving the preconditions through an interface, the preconditions may be saved and accessed through a memory.

Some embodiments disclosed herein discuss a test and measurement instrument that may learn and save key parameters of a current test and measurement instrument configuration and then reapply these key parameters to configure the test and measurement instrument accordingly in subsequent data acquisitions. In some embodiments, the key parameters may be converted to conditional preconditions, as will be discussed in more detail below, to be applied during subsequent data acquisitions and/or in other environments.

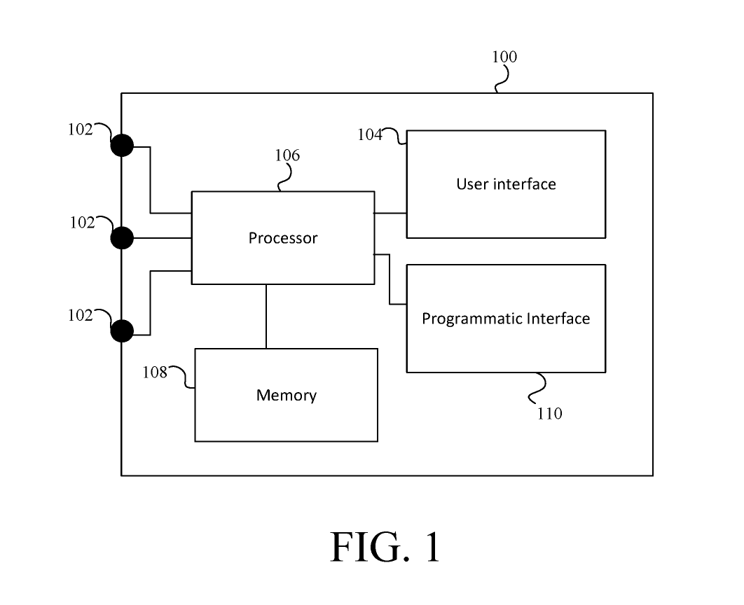

FIG. 1 is a block diagram of an example test and measurement system, according to some embodiments disclosed herein. A test and measurement instrument 100 may include, among other components not shown, one or more input channels 102 to connect to a device under test and receive data or signals from the device under test. The test and measurement instrument 100 may also include a user interface 104 to receive input from a user, such as by knobs, buttons, touchscreen, etc., and output data to a user, such as through a display, as will be understood by one skilled in the art. The one or more input channels 102 and the user interface 104 are each connected to one or more processors 106. The one or more processors 106 receive and process or analyze data, also referred to herein as signals or waveforms, from the device under test 120 for display on the user interface 104 and/or for storage in one or more memories 108 to be accessed at later time. While FIG. 1 shows only one processor 106 and one memory 108, one of ordinary skill in the art would readily appreciate that multiple processors 106 and memories 108 may be present and electrically connected to each other.

The test and measurement instrument 100 also includes a programmatic interface (PI) 110 connected to the one or more processors 106. The PI 110 receives instructions and sends the instructions to the one or more processors 106 to implement. The PI 110 may receive instructions through a wired or wireless communication from a separate device, or in some embodiments, the PI 110 may be included in the user interface 104 of the test and measurement instrument 100 and a user may interact with the PI 110 through the user interface 104. Further, although not shown, in some embodiments, the measurement preconditions may be received directly at the user interface 104, rather than through the PI 110.

For example, test programs may be written to interact with the settings of the test and measurement instrument 100 using PI commands received at the PI 110 to get data received through one of the channels 102 into a state that is valid for making a measurement. The data received after the PI commands are received can result in a waveform that the test and measurement instrument 100 can use for getting results from built-in measurements of the one or more processors 106 or by extracting the waveform from the test and measurement instrument 100 and performing the measurement on a remote device.

Typical PI 110 commands are designed to control individual settings of an instrument to create the test programs. For example, on an oscilloscope, one PI command such as

SELECT:CH1

may turn on Channel 1 of the oscilloscope, another command such as

CH1:SCALE 0.1

may set the vertical scale of Channel 1 to 100 mV/div, and another command such as

HORIZONTAL: SCALE 0.02

may set the timebase of the oscilloscope to 20 ms/div, etc.

To set up the test and measurement instrument 110 to make a complex measurement, such as displaying an eye diagram on an oscilloscope, a user must issue a complex sequence of PI 110 commands to the test and measurement instrument 100. The process of setting up the test and measurement instrument 100 using test programs is time-consuming, requires an understanding of the test and measurement instrument's operation, is potentially error prone, and may require changing the programming to achieve the same results between different test and measurement instruments since different test and measurement instruments may have different sets of available PI commands. It is also possible that by using test programs, the test and measurement instrument may silently coerce requested values to other values which can unintentionally invalidate the application of the acquired waveform for a required measurement.

Embodiments of the disclosure, however, use the PI 110 to associate measurement preconditions with data acquisition, such as a waveform or measurement, rather than to control individual settings of the test and measurement instrument 100. Embodiments of the disclosure allow for commands to configure the test and measurement instrument 100 as needed to perform the data acquisition resulting in the waveform or measurement conforming with a desired measurement precondition. If the test and measurement instrument 100 cannot be configured to meet the measurement preconditions, an error may be returned. This allows the same PI 110 commands to be used no matter the test and measurement instrument 100 and does not require complex commands to set every setting of the test and measurement instrument 100 via a command—rather, the test and measurement instrument 100 receives the measurement precondition and configures the test and measurement instrument 100 as needed for data acquisition to meet the measurement precondition.

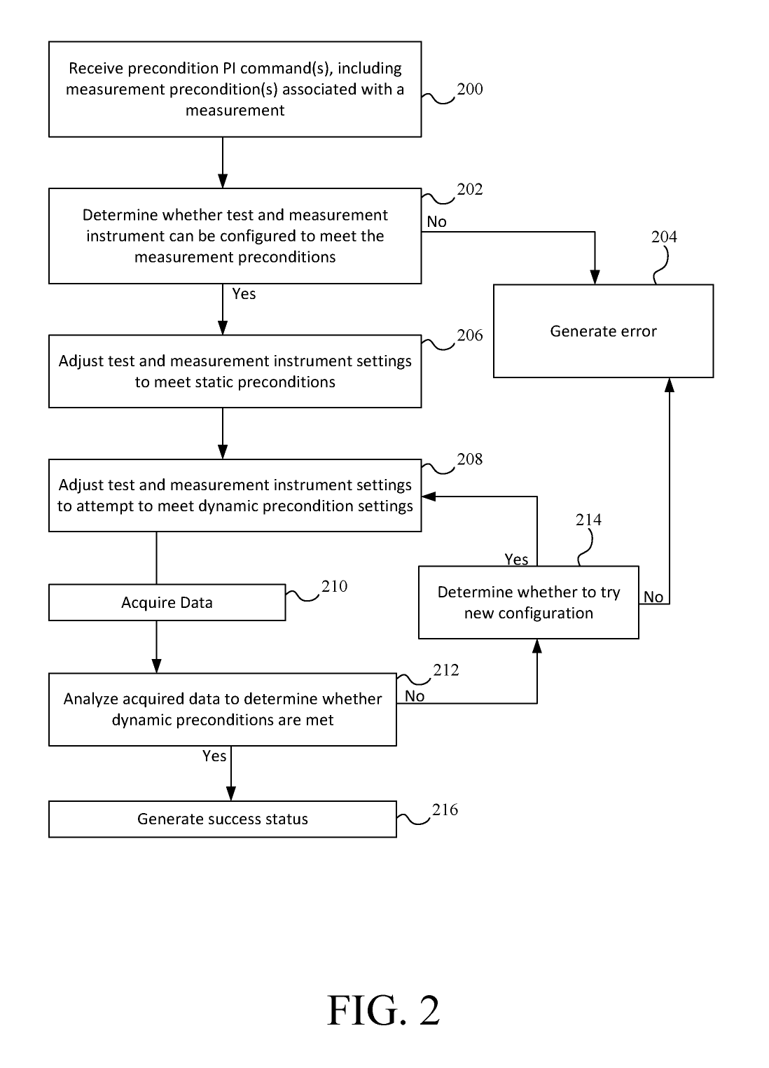

FIG. 2 illustrates an operation for configuring the test and measurement instrument 100 in response to the measurement preconditions. Initially, in operation 200, preconditions are received, either at the PI 110 or the user interface 104, including measurement preconditions associated with a particular measurement. In operation 202, the test and measurement instrument 100 determines whether the test and measurement instrument 100 can be configured to meet the measurement preconditions. If no, then in operation 204, the one or more processors 106 generate one or more alerts to indicate an error. In some embodiments, the data may still be acquired, but may be returned to the user with an error indicating that the one or more of the measurement preconditions was not met. For example, if multiple measurement preconditions are provided, the user interface 104 may output the acquired data as well as an alert or error signal indicating which measurement preconditions were not met, in the event that the data may still be useful to a user.

Measurement preconditions may include, for example, a number of unit intervals for the data, a number of samples per unit interval, maximize signal-to-noise ratio (SNR), optimized visualization on the graticule, a number of edges for the data, etc. Measurement preconditions, however, are not limited to the above-noted examples. Rather, the measurement precondition can be any type of measurement condition that a user may desire or require for a particular measurement or data acquisition. For example, many standards, such as PCI Express Gen 3, require a specified number of unit intervals for a measurement and the measurement preconditions allow a user to specify that type of measurement precondition, so that test and measurement instrument 100 may configure its settings to acquire data that meets the measurement precondition.

Measurement preconditions may be either static or dynamic. For example, static measurement preconditions are measurement preconditions that are not data dependent. That is, static measurement preconditions are measurement settings that may not be expected to adjust based on underlying waveform data, such as a horizontal or vertical scale for the display. In contrast, dynamic measurement preconditions are measurement preconditions that are waveform or data related measurements that are preconditions for additional analysis. A required number of edges in the data or a specific amplitude for the data are examples of dynamic measurement preconditions since the measurement preconditions are data dependent. Since these types of measurement preconditions are data dependent, it may require several data acquisitions to configure the test and measurement instrument to adjust the data to meet the measurement precondition.

Returning to FIG. 2, if the test and measurement instrument 100 can be configured to meet the measurement precondition, then in operation 206, the test and measurement instrument is adjusted, or configured, to meet the static measurement preconditions, if any.

As mentioned above, to configure the test and measurement instrument 100 for dynamic measurement preconditions, data must first be acquired. Accordingly, in some embodiments, if dynamic measurement preconditions are received, in operation 208, the test and measurement instrument 100 configures itself to attempt to meet the dynamic measurement preconditions, if any. Then, in operation 210, data is acquired. In operation 212, the acquired data is analyzed to determine whether the dynamic measurement preconditions are met.

If the dynamic measurement preconditions are not met, then in operation 214, the test and measurement instrument 100 determines whether a new configuration could be applied to meet the dynamic measurement preconditions. If yes, the operation returns to operation 212. If no, then one or more error messages are generated by the one or more processors 106.

If the dynamic measurement preconditions are met, then in operation 216 a success status is generated by the one or more processors 106 and the data may be output to the user interface 104 and/or saved in memory 108.

The measurement preconditions may be conditional and may be combined into a single measurement precondition command. For example, conditional expressions, such as and, or, not, equal to, greater than, etc. may be used. The following is an example precondition command:

:PRECONDITION:CH1 “UI=2.7 GHz, UI.Count>=100 K, MaximizeSNR=true, SamplesPerUI>=8”

In this example precondition command, “:PRECONDITION:CH1” is an identifier of the precondition command and indicates that the command applies to data received at channel 1 of the one or more channels 102 of the test and measurement instrument 100. “UI=2.7 GHz” is a first measurement precondition included in the command, stating the unit interval should be 2.7 GHz for the data. “UI.Count>=100 k is the second measurement precondition, stating that the number of unit intervals included should be greater than or equal to 100,000. “MaximizeSNR=true” is the third measurement precondition in the precondition command and indicates that the SNR of the data should be maximized. Finally, the precondition command includes the fourth measurement precondition “SamplesPerUI>=8” which states that the number of data samples for each unit interval should be equal to or greater than eight. In some embodiments, an error signal may be generated by the one or more processors 106 when the PI command is received that includes a combination of measurement preconditions that become nonsensical when combined, such as defining two different size unit intervals, for example.

Various precondition commands and measurement preconditions may be saved in the one or more memories 108 with an identifier and accessed later by the PI 110 or the user interface 104. For example, a precondition command may be for a specific channel or may be for a specific set up of a specific channel, and such may be stored in the one or more memories 108 so that a user does not have to enter the precondition command each time the test and measurement instrument 100 setup is desired.

Further, a precondition command may be used to execute a specific precondition command. For example, to execute the precondition command above, another precondition command may be used, such as:

:PRECONDITION:CH1:EXECUTE

If multiple channels of an instrument have precondition commands pending, then a command :PRECONDITION:ALL:EXECUTE could be used to execute the precondition commands on all the channels. However, the intersection of preconditions may result in no common settings. In that case, the command will attempt to attain settings the maximizes the number of channels that the setting applies to or, in some embodiments, the test and measurement instrument 100 may simply return an error.

To verify that preconditions have been met by the instrument, a user can use the following PI command query:

:PRECONDITION::CH1:STATUS?

In response to the query, a status is returned to a user. For example, the status may be a “1” or “0”, with “1” indicating status was achieved and “0” indicating the status was not achieved. Other types of statuses may also be generated by the one or more processors 106 to indicate any errors. That is, the status may be “error,” “no error,” “okay,” or “fail,” etc.

Using the precondition command discussed above, :PRECONDITION:CH1 “UI=2.7 GHz, UI.Count>=100 K, MaximizeSNR=true, SamplesPerUI>=8”, the one or more processors 106 of the test and measurement instrument 100 can configure the test and measurement instrument 100 and its various components to achieve these measurement preconditions for acquired data.

For example, the horizontal settings can be configured by calculating the target width of a sample based on the unit interval size of 2.7 GHz and the samples per unit interval, and determining from that information a sample rate request. If the sample rate request is unavailable in the test and measurement instrument 100, then the one or more processors 106 may round out the sample rate request to the nearest supported sample rate. Then, using the desired number of unit intervals (100,000), a duration of the record is calculated, which can be used to determine the length of the record, to set the horizontal settings.

If the unit interval had not been specified in the precondition command, then test and measurement instrument 100 would attempt to capture a few hundred edges of the data and then estimate the unit interval. This estimated value would then be applied to determine the horizontal settings, which may require multiple acquisitions, resulting in the data content being relevant to the setup, which is an example of a dynamic precondition.

Since there is not a measurement precondition included in the precondition command related to the vertical settings, the one or more processors 106 of the test and measurement instrument 100 would make an amplitude measurement, center the waveform or data, and then set a vertical scale to the nearest amplitude divided by ten, as would be understood by one skilled in the art.

As mentioned above, measurement preconditions may also be used to validate signal, or data, content. For example, the example precondition command above requires 100,000 edges, which is very signal dependent. To configure the test and measurement instrument 100 for this measurement precondition, the horizontal and vertical setup must be performed, and then the results analyzed for additional refinement.

For example, if the results from the horizontal and vertical setup achieved 20,000 edges, then the horizontal scale would need to be increased by five times. The one or more processors 106 would implement this change, and then acquire data again and check to determine if the data meets the measurement precondition. If not, adjustments may be made again, or an error may be generated when the one or more processors 106 determine that no further adjustments to the test and measurement instrument 100 can make data align with the measurement precondition.

In some embodiments, measurement preconditions may be associated with measurement requests via the PI 110 or user interface 104. Many of the measurements associated with a measurement of interest (MOI) may be predefined to ensure reproducible results. As mentioned above, however, meeting the measurement precondition might require multiple data acquisitions. By analyzing the measurement preconditions, the number of acquisitions may be minimized by combining measurements with intersecting measurement preconditions.

In some embodiments of the disclosure, the measurement preconditions may be determined based on current settings of the test and measurement instrument 100, rather than received through the PI 110 or the user interface 104. These measurement preconditions may be determined based on the current settings of the test and measurement instrument 100 and saved in the one or more memories 108, with an identifier for example, and reapplied by a user as desired. That is, the test and measurement instrument 100 may learn a particular configuration that a user may be able to apply to subsequent data acquisitions, without having to manually reconfigure the test and measurement instrument for each subsequent data acquisition.

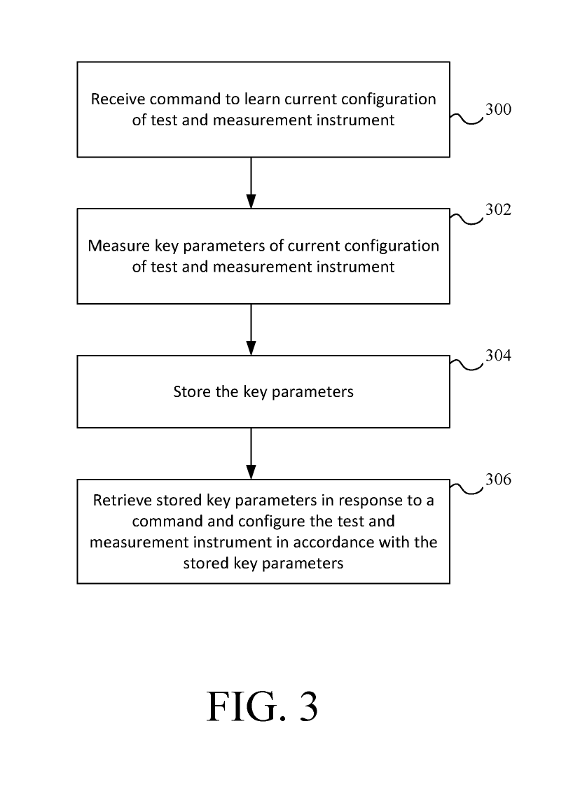

For example, FIG. 3 illustrates an operation for determining measurement preconditions based on the current settings of the test and measurement instrument 100. Initially, in operation 300, a command is received, through either the PI 110 or the user interface 104, to learn the current settings, or configuration, of the test and measurement instrument 100. For example, a user may configure the test and measurement instrument 100 using the user interface 104 for a particular waveform to measure a particular feature of the data or to view the data. Once the user has the test and measurement instrument 100 configured in the desired manner, then the user may request, either through the user interface 104 or the PI 110, that the test and measurement instrument 100 save the setup for use during future data acquisitions. In some embodiments, the user may indicate an identifier to use in relation to the saved setup.

In operation 302, parameters of the current settings of the test and measurement instrument 100 are measured. For example, the parameters for each waveform may include such parameters as edge density, height (in divisions), location of a center of the waveform (in division), and trigger offset from a center of the waveform. However, as would be understood by one skilled in the art, additional parameters may be saved. In some embodiments, the parameters to be saved for the current configuration may be entered into the PI 110 or the user interface 104 by a user.

In operation 304, the parameters may be stored as measurement preconditions, as discussed above. However, in some embodiments, the parameters may be stored separately in the one or more memories 108 and implemented directly by the one or more processors 106 without the PI 110. As also mentioned above, these parameters may be stored along with an identifier such that the group of parameters are stored together and implemented together.

In some embodiments, when the parameters are stored as measurement preconditions, the parameters may be stored as conditional statements, as discussed above. For example, if the current settings of the test and measurement instrument includes five edges, then the measurement precondition may be saved as greater than or equal to five edges, to allow other rules to also be applied. That is, the measurement precondition stored based on the current settings may be a minimum rather than the actual current setting or display of the data. Further, in some embodiments, a user may modify the stored measurement precondition or parameter prior to the measurement precondition or parameter being stored.

In operation 306, if a command is received, either through the user interface 104 or PI 110 to implement the saved parameters, then the parameters are retrieved from the one or more memories 108 and are used to configure the test and measurement instrument 100 to display and process the currently received data in light of the saved parameters. Although not shown in FIG. 3, similar to above, if the one or more processors 106 are not able to configure the test and measurement instrument 100 to display and/or analyze the data in accordance with the saved parameters, then the one or more processors 106 may generate an error message to a user or set an error flag.

This allows a user to intuitively define measurement parameters for use in configuring the test and measurement instrument 100, rather than providing explicit measurement parameters through the PI 110 or the user interface 104. This may help streamline the interaction of a probe, test and measurement instrument, and circuitry while still allowing a user to have data positioned and scaled in the best way for a particular application.

Embodiments of the disclosure discussed herein reduce the effort required to setup an instrument to make a valid measurement. The user can define a precondition in a way that makes sense in the context of the measurement to be made. The test and measurement instrument 100 is then either required to attain that precondition or note its inability to meet the precondition. This is highly valuable because it takes much of the burden off the developer of test programs in a way that allows them to focus on their measurements rather than the nuances of a piece of test and measurement equipment. Embodiments disclosed herein also significantly reduces the effort required to create applications and increases the repeatability of measurements across different test and measurement instrument families

The aspects of the present disclosure are susceptible to various modifications and alternative forms. Specific aspects have been shown by way of example in the drawings and are described in detail herein below. However, it should be noted that the examples disclosed herein are presented for the purposes of clarity of discussion and are not intended to limit the scope of the general concepts disclosed to the specific aspects described herein unless expressly limited. As such, the present disclosure is intended to cover all modifications, equivalents, and alternatives of the described aspects in light of the attached drawings and claims.

References in the specification to aspect, example, etc., indicate that the described item may include a particular feature, structure, or characteristic. However, every disclosed aspect may or may not necessarily include that particular feature, structure, or characteristic. Moreover, such phrases are not necessarily referring to the same aspect unless specifically noted. Further, when a particular feature, structure, or characteristic is described in connection with a particular aspect, such feature, structure, or characteristic can be employed in connection with another disclosed aspect whether or not such feature is explicitly described in conjunction with such other disclosed aspect.

Aspects of the disclosure may operate on a particularly created hardware, on firmware, digital signal processors, or on a specially programmed computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the technologies disclosed herein are provided below. An embodiment of the technologies may include any one or more, and any combination of, the examples described below.

Example 1 is a test and measurement instrument, comprising an interface configured to receive one or more preconditions for data acquisition, the one or more preconditions defining one or more rules to which data received during the data acquisition is to conform; and one or more processors. The one or more processors are configured to receive the one or more preconditions for data acquisition, determine whether the test and measurement instrument can be configured to implement the one or more preconditions for data acquisition, configure the test and measurement instrument to implement the one or more preconditions for data acquisition when the test and measurement instrument can be configured to implement the one or more preconditions for data acquisition, and generate one or more alerts when the test and measurement instrument cannot be configured to implement the one or more preconditions for data acquisition.

Example 2 is the test and measurement instrument of example 1, wherein the one or more preconditions are static preconditions.

Example 3 is the test and measurement instrument of example 1, wherein the one or more preconditions are dynamic preconditions and the one or more processors are further configured to receive data during the data acquisition; determine whether the received data conforms to the one or more preconditions; and generate one or more alerts when the data does not conform to the one or more preconditions.

Example 4 is the test and measurement instrument of example 3, wherein the one or more processors are further configured to configure the test and measurement instrument in response to the received data and the one or more preconditions.

Example 5 is the test and measurement instrument of any one of examples 1-4, wherein the interface is a programmatic interface.

Example 6 is the test and measurement instrument of any one of examples 1-5, wherein the interface is a user interface.

Example 7 is t test and measurement instrument of any one of examples 1-6, wherein the one or more preconditions are conditional.

Example 8 is the test and measurement instrument of any one of examples 1-7, further comprising a memory configured to store the one or more preconditions for data acquisition, wherein the interface is further configured to receive the one or more preconditions for data acquisition from the memory.

Example 9 is the test and measurement instrument of example 8, wherein the one or more processors are further configured to determine a current configuration of a test and measurement instrument; and based on the current configuration, determine the one or more preconditions to store in the memory.

Example 10 is the test and measurement instrument of example 8 or 9, wherein the memory is further configured to store a plurality of identifiers, each identifier indicating one or more preconditions for a particular test and measurement instrument configuration.

Example 11 is the method of any one of examples 1-10, wherein the one or more processors are further configured to receive two or more preconditions for the data acquisition, wherein at least one precondition is a static precondition and at least one precondition is a dynamic precondition.

Example 12 is a method for configuring a test and measurement instrument for data acquisition, the method comprising receiving one or more preconditions for data acquisition, the one or more preconditions defining one or more rules to which data received during the data acquisition is to conform; determining whether the test and measurement instrument can be configured to implement the one or more preconditions for data acquisition; configuring the test and measurement instrument to implement the one or more preconditions for data acquisition so that the acquired data meets the one or more preconditions when the test and measurement instrument can be configured to implement the one or more preconditions for data acquisition, and generating one or more alerts when the test and measurement instrument cannot be configured to implement the one or more preconditions for data acquisition.

Example 13 is the method of example 12, wherein the one or more preconditions are a static precondition.

Example 14 is the method of example 12, wherein the one or more preconditions are dynamic preconditions and the method further comprises acquiring data during the data acquisition; determining whether the received data conforms to the one or more preconditions; and generating one or more alerts when the data does not conform to the one or more preconditions.

Example 15 is the method of example 14, further comprising configuring the test and measurement instrument in response to the acquired data and the one or more preconditions.

Example 16 is the method of any one of examples 12-15, wherein the one or more preconditions are conditional.

Examples 17 is the method of any one of examples 12-16, further comprising determining a current configuration of a test and measurement instrument; determining the one or more preconditions based on the current configuration of the test and measurement instrument; storing the one or more preconditions determined based on the current configuration of the test and measurement instrument; and receiving the one or more preconditions from the memory.

Example 18 is the method of any one of examples 12-17, further comprising storing a plurality of identifiers, each identifier indicating one or more preconditions for a particular test and measurement instrument configuration.

Example 19 is the method of any one of examples 12-18, further comprising receiving two or more preconditions for data acquisition; determining whether the two or more preconditions are compatible; and generating an alert when the two or more preconditions are not compatible.

Example 20 is the method of any one of examples 12-19, further comprising receiving two or more preconditions for data acquisition, wherein at least one precondition is a static precondition and at least one precondition is a dynamic precondition.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure. Accordingly, the disclosure should not be limited except as by the appended claims.

What is claimed is:

1. A test and measurement instrument, comprising:
an interface configured to receive one or more preconditions for data acquisition, the one or more preconditions defining one or more rules to which data received during the data acquisition is to conform; and
one or more processors configured to:
receive the one or more preconditions for data acquisition,
determine whether the test and measurement instrument can be configured to implement the one or more preconditions for data acquisition,
configure the test and measurement instrument to implement the one or more preconditions for data acquisition when the test and measurement instrument can be configured to implement the one or more preconditions for data acquisition, and
generate one or more alerts when the test and measurement instrument cannot be configured to implement the one or more preconditions for data acquisition.

2. The test and measurement instrument of claim 1, wherein the one or more preconditions are static preconditions.

3. The test and measurement instrument of claim 1, wherein the one or more preconditions are dynamic preconditions, and the one or more processors are further configured to:
receive data during the data acquisition;
determine whether the received data conforms to the one or more preconditions; and
generate one or more alerts when the data does not conform to the one or more preconditions.

4. The test and measurement instrument of claim 3, wherein the one or more processors are further configured to:
configure the test and measurement instrument in response to the received data and the one or more preconditions.

5. The test and measurement instrument of claim 1, wherein the interface is a programmatic interface.

6. The test and measurement instrument of claim 1, wherein the interface is a user interface.

7. The test and measurement instrument of claim 1, wherein the one or more preconditions are conditional.

8. The test and measurement instrument of claim 1, further comprising a memory configured to store the one or more preconditions for data acquisition, wherein the interface is further configured to receive the one or more preconditions for data acquisition from the memory.

9. The test and measurement instrument of claim 8, wherein the one or more processors are further configured to:
determine a current configuration of a test and measurement instrument; and
based on the current configuration, determine the one or more preconditions to store in the memory.

10. The test and measurement instrument of claim 8, wherein the memory is further configured to store a plurality of identifiers, each identifier indicating one or more preconditions for a particular test and measurement instrument configuration.

11. The method of claim 1, wherein the one or more processors are further configured to receive two or more preconditions for the data acquisition, wherein at least one precondition is a static precondition and at least one precondition is a dynamic precondition.

12. A method for configuring a test and measurement instrument for data acquisition, the method comprising:
receiving one or more preconditions for data acquisition, the one or more preconditions defining one or more rules to which data received during the data acquisition is to conform;
determining whether the test and measurement instrument can be configured to implement the one or more preconditions for data acquisition;
configuring the test and measurement instrument to implement the one or more preconditions for data acquisition so that the acquired data meets the one or more preconditions when the test and measurement instrument can be configured to implement the one or more preconditions for data acquisition, and
generating one or more alerts when the test and measurement instrument cannot be configured to implement the one or more preconditions for data acquisition.

13. The method of claim 12, wherein the one or more preconditions are a static precondition.

14. The method of claim 12, wherein the one or more preconditions are dynamic preconditions and the method further comprises:
acquiring data during the data acquisition;
determining whether the received data conforms to the one or more preconditions; and
generating one or more alerts when the data does not conform to the one or more preconditions.

15. The method of claim 14, further comprising configuring the test and measurement instrument in response to the acquired data and the one or more preconditions.

16. The method of claim 12, wherein the one or more preconditions are conditional.

17. The method of claim 12, further comprising:
determining a current configuration of a test and measurement instrument;
determining the one or more preconditions based on the current configuration of the test and measurement instrument;
storing the one or more preconditions determined based on the current configuration of the test and measurement instrument; and
receiving the one or more preconditions from the memory.

18. The method of claim 12, further comprising storing a plurality of identifiers, each identifier indicating one or more preconditions for a particular test and measurement instrument configuration.

19. The method of claim 12, further comprising:
receiving two or more preconditions for data acquisition;
determining whether the two or more preconditions are compatible; and
generating an alert when the two or more preconditions are not compatible.

20. The method of claim 12, further comprising receiving two or more preconditions for data acquisition, wherein at least one precondition is a static precondition and at least one precondition is a dynamic precondition.
